(19) United States
(12) Patent Application Publication
(10) Pub. No.: US 2014/0061890 A1
(43) Pub. Date: Mar. 6, 2014

(54) SEMICONDUCTOR PACKAGE AND METHOD OF MANUFACTURING THE SAME

(71) Applicant: Samsung Electronics Co., Ltd., Suwon-si (KR)

(72) Inventors: Jung-Do Lee, Uiwang-si (KR); Taewoo Kang, Suwon-si (KR); Donghan Kim, Osan-si (KR); JongBo Shim, Asan-si (KR); Yang-hoon Ahn, Asan-si (KR); SeokWon Lee, Seongnam-si (KR); Dae-young Choi, Yeosu-si (KR)

(73) Assignee: Samsung Electronics Co., Ltd., Suwon-si (KR)

(21) Appl. No.: 14/013,714

(22) Filed: Aug. 29, 2013

(30) Foreign Application Priority Data
Aug. 30, 2012 (KR) 10-2012-0095590

(51) Int. Cl. H01L 23/34

(52) U.S. Cl. CPC H01L 23/34
USPC 257/701

(57) ABSTRACT

A semiconductor package may include a semiconductor chip mounted on a substrate, a molding part protecting the semiconductor chip and having a top surface at a substantially equal height to a top surface of the semiconductor chip, a heat exhausting part on the molding part and the semiconductor chip, and an adhesive part between the heat exhausting part and the molding part and between the heat exhausting part and the semiconductor chip. An interface between the heat exhausting part and the adhesive part has a concave-convex structure.

### CROSS-REFERENCE TO RELATED APPLICATIONS

This U.S. non-provisional patent application claims priority under 35 U.S.C. §119 to Korean Patent Application No. 10-2012-0095590, filed on Aug. 30, 2012, in the Korean Intellectual Property Office, the contents of which are herein incorporated by reference in their entirety.

### BACKGROUND

The inventive concepts relate to semiconductor packages and methods of manufacturing the same. More particularly, the inventive concepts related to semiconductor packages including heat exhausting parts and methods of manufacturing the same.

Semiconductor devices have been more highly integrated which results in various problems. For example, a process margin of an exposure process defining fine patterns may be reduced. Thus, it may be difficult to realize the semiconductor devices. Additionally, high speed semiconductor devices have been increasingly in demand. Various studies have been conducted to solve the problems of high speed and/or high integration.

### SUMMARY

Embodiments of the inventive concepts may provide highly integrated semiconductor packages.

Embodiments of the inventive concepts may also provide methods of manufacturing a highly integrated semiconductor package.

According to an aspect of the present inventive concepts, a semiconductor package may include: a semiconductor chip mounted on a substrate; a molding part protecting the semiconductor chip, the molding part having a top surface at a height substantially equal to that of a top surface of the semiconductor chip; a heat exhausting part on the molding part and the semiconductor chip; and an adhesive part between the heat exhausting part and the molding part and between the heat exhausting part and the semiconductor chip. An interface between the heat exhausting part and the adhesive part may have a concave-convex structure.

In some embodiments, the concave-convex structure may be at the heat exhausting part.

In some embodiments, the molding part may have an exposed molded underfill (eMUF) structure exposing the top surface of the semiconductor chip.

In some embodiments, the semiconductor package may further include: connection patterns disposed between the semiconductor chip and the substrate. The connection patterns may electrically connect the semiconductor chip to the substrate; and the molding part may cover the connection patterns.

According to another aspect of the present inventive concepts, a method of manufacturing a semiconductor package may include: mounting a semiconductor chip on a substrate; forming a molding part which exposes a top surface of the semiconductor chip and covers a sidewall and a bottom surface of the semiconductor chip; preparing a heat exhausting part having a concave-convex structure formed at one surface of the heat exhausting part; forming an adhesive part on the one surface of the heat exhausting part; and adhering the heat exhausting part having the adhesive part to the molding part and the semiconductor chip.

In some embodiments, the concave-convex structure may be formed using a laser at the one surface of the heat exhausting part.

In some embodiments, the concave-convex structure may be formed using a mold.

In some embodiments, the method may further include: forming connection patterns on one surface of the semiconductor chip; and bonding the connection patterns to one surface of the substrate.

In some embodiments, the molding part may be formed to cover the connection patterns and a sidewall and a bottom surface of the semiconductor chip simultaneously.

According to another aspect of the present inventive concepts, a semiconductor package may include a semiconductor chip mounted on a substrate, a molding part protecting the semiconductor chip and exposing a top surface of the semiconductor chip, a heat exhausting part on the molding part and the semiconductor chip, a first surface of the heat exhausting part having a concave-convex structure, and an adhesive part between the top surface of the semiconductor chip and the heat exhausting part filling concave regions of the concave-convex structure.

In some embodiments, the molding part covers a sidewall and a bottom surface of the semiconductor chip.

In some embodiments, the molding part has an exposed molded underfill (eMUF) structure exposing the top surface of the semiconductor chip.

In some embodiments, the adhesive part is further between the molding part and the heat exhausting part.

In some embodiments, the semiconductor package further includes connection patterns disposed between the semiconductor chip and the substrate and the connection patterns electrically connect the semiconductor chip to the substrate and the molding part covers the connection patterns.

In some embodiments, the molding part comprises a top surface at a height substantially equal to that of a top surface of the semiconductor chip.

In some embodiments, the semiconductor chip comprises a plurality of semiconductor chips vertically stacked. In some embodiments, the plurality of semiconductor chips are at least one of electrically connected to the substrate and electrically connected to each other. In some embodiments, at least one of the plurality of semiconductor chips comprises a through-electrode.

In some embodiments, the concave-convex structure comprises at least one of convex portions along rows and columns at equal intervals, convex portions at irregular intervals, convex portions only along outer edges of the heat exhausting part, a partition structure, convex portions having line-shapes, and convex portions having a mesh structure.

In some embodiments, the semiconductor package further comprises external terminals at a surface of the substrate opposite the surface of the substrate to which the semiconductor chip is mounted

### BRIEF DESCRIPTION OF THE DRAWINGS

The foregoing and other features and advantages of the inventive concepts will be apparent from the more particular description of embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIGS. 1A through 1C are cross-sectional views illustrating semiconductor packages according to example embodiments of the inventive concepts.

FIGS. 2A through 2G are plan views illustrating concave-convex structures of heat exhausting parts of semiconductor packages according to example embodiments of the inventive concepts.

FIGS. 3A through 3C are cross-sectional views illustrating a method of manufacturing a semiconductor package according to example embodiments of the inventive concepts.

FIG. 4A is schematic block diagram illustrating a memory card including semiconductor packages according to example embodiments of the inventive concepts.

FIG. 4B is schematic block diagram illustrating a system including semiconductor packages according to example embodiments of the inventive concepts.

### DETAILED DESCRIPTION OF THE EMBODIMENTS

Various example embodiments of the inventive concepts will be described more fully hereinafter with reference to the accompanying drawings, in which some example embodiments are shown. The present inventive concepts may, however, be embodied in many different forms and should not be construed as limited to the example embodiments set forth herein.

The terminology used herein is for the purpose of describing particular example embodiments only and is not intended to limit the present inventive concepts. As used herein, the singular terms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be also understood that, although, the terms first, second, third etc. may be used herein to describe various elements, components, regions, layers and/or sections, these elements, components, regions, layers and/or sections should not be limited by these terms. These terms are only used to distinguish one element, component, region, layer and/or section from another element, component, region, layer and/or section. Thus, a first element, component, region, layer and/or section described below could be termed a second element component, region, layer and/or section without departing from the teachings of the present inventive concepts.

Example embodiments are described with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the present inventive concepts.

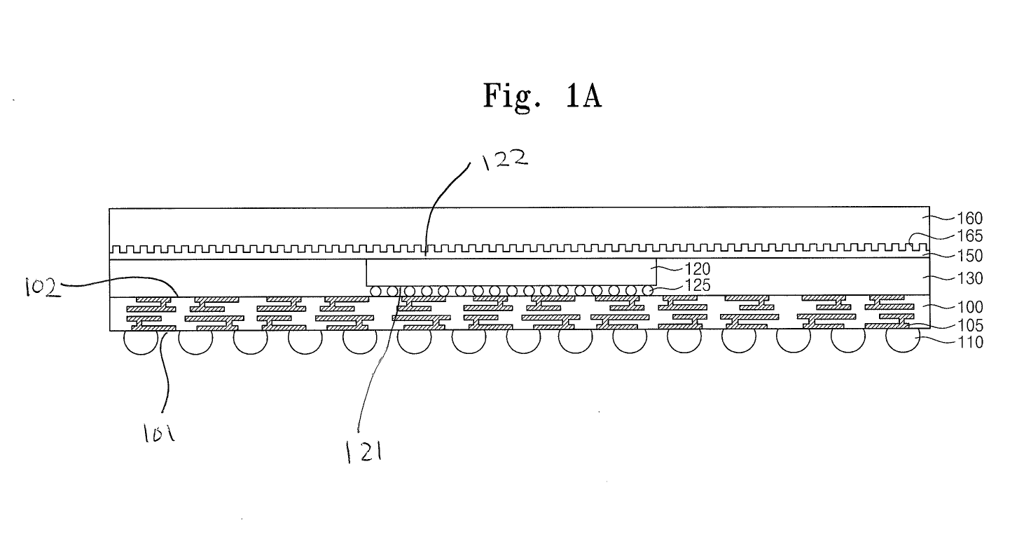

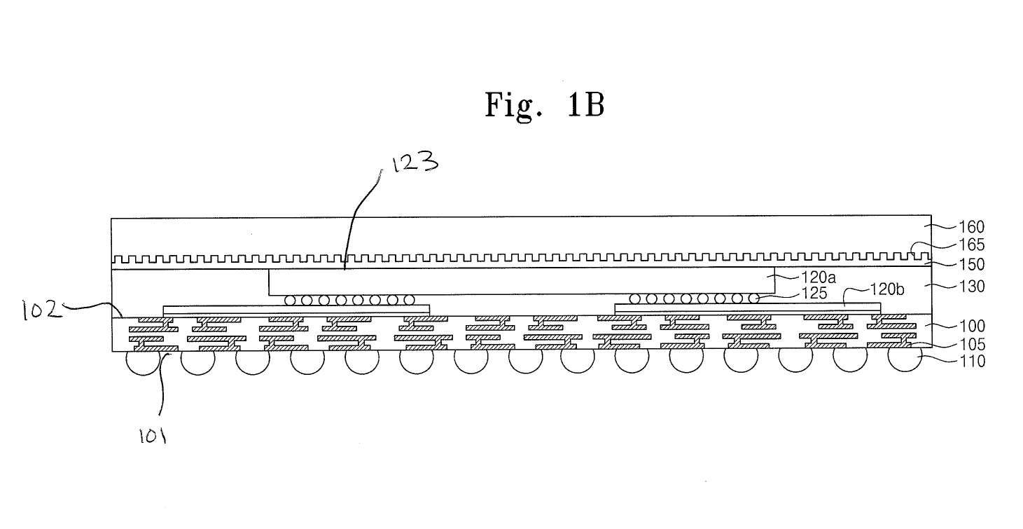

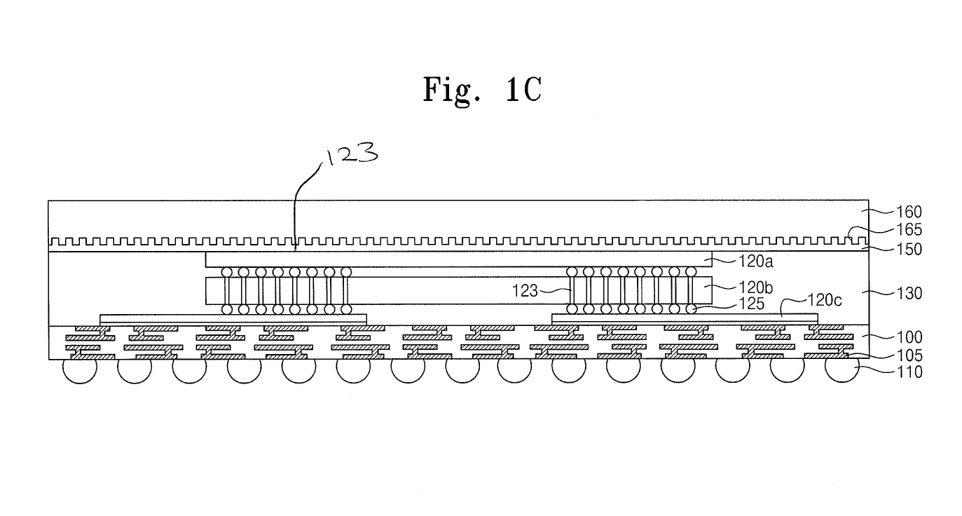

FIG. 1A is a cross-sectional view illustrating a semiconductor package according to an example embodiment of the inventive concepts, and FIG. 1B is a cross-sectional view illustrating a semiconductor package according to another example embodiment of the inventive concepts, and FIG. 1C is a cross-sectional view illustrating a semiconductor package according to another example embodiment of the inventive concepts.

Referring to FIGS. 1A through 1C, a semiconductor package may include a substrate 100, a semiconductor chip 120, connection patterns 125, a molding part 130, an adhesive part 150, and a heat exhausting part 160.

The substrate 100 may be a printed circuit board (PCB). The substrate 100 may include a first surface 101 connected to external terminals 110 and a second surface 102 on which the semiconductor chip 120 is mounted. Exposed pads 105 may be formed on the first surface 101 and the second surface 102 of the substrate 100. The external terminals 110 may be solder balls.

Referring to FIG. 1A, the semiconductor chip 120 may be mounted on the second surface 102 of the substrate 100. The semiconductor chip 120 may include a first surface 121 facing the substrate 100 and a second surface 122 opposite to the first surface 121.

Referring to FIG. 1B, a plurality of semiconductor chips 120a and 120b may be vertically stacked. For example, semiconductor chip 120a may be stacked on semiconductor chips 120b, as illustrated in FIG. 1B. The semiconductor chips 120a and 120b may be electrically connected to the substrate 100 and/or be electrically connected to each other.

Referring to FIG. 1C, a plurality of semiconductor chips 120a, 120b, and 120c may be mounted on the substrate 100, and at least one of the semiconductor chips 120a, 120b, and 120c may include at least one through-electrode 123. For example, the semiconductor chip 120b includes a plurality of through-electrodes 123, as illustrated in FIG. 1C. The plurality of semiconductor chips 120a, 120b, and 120c may be vertically stacked. For example, semiconductor chip 120a may be stacked on semiconductor chip 120b and semiconductor chip 120b may be stacked on semiconductor chip 120c, as illustrated in FIG. 1C. The semiconductor chips 120a, 120b, and 120c may be electrically connected to the substrate 100 and/or be electrically connected to each other.

As illustrated in FIG. 1A, the connection patterns 125 may be disposed between the second surface 102 of the substrate 100 and the first surface 121 of the semiconductor chip 120, and the semiconductor chip 120 may be electrically connected to the substrate 100 through the connection patterns 125. The connection patterns 125 may be solder balls or bumps.

The molding part 130 may have an exposed molded underfill (eMUF) structure. Specifically, the eMUF structure of the molding part 130 may expose the second surface 122 of the semiconductor chip 120 and completely cover or surround a sidewall and the first surface 121 of the semiconductor chip 120. Additionally, the eMUF structure may also cover or surround the connection patterns 125 disposed between the substrate 100 and the semiconductor chip 120. In some embodiments, the eMUF structure of the molding part 130 may be a combined structure including a general underfill covering connection patterns 125 and a mold covering the semiconductor chip 120. Thus, the molding part 130 may have a first portion covering the connection patterns 125 and a second portion covering the semiconductor chip 120, and the first portion of the molding part 130 may be connected to (or in contact with) the second portion of the molding part 130 without an interface therebetween. Additionally, due to the molding part 130, an additional processing step for forming an underfill is not required, and, thus, the method of manufacturing the semiconductor device may be simplified.

According to the example embodiments illustrated in FIGS. 1B and 1C, the molding part 130 may expose a top surface 123 of an uppermost semiconductor chip 120a. The semiconductor chips 120b and 120c under the uppermost semiconductor chip 120a may be completely covered or surrounded by the molding part 130.

The heat exhausting part 160 may absorb heat occurring within the semiconductor package and, then, the heat exhausting part 160 exhausts the heat. Additionally, the heat exhausting part 160 may absorb heat inputted from an external system and, then, the heat exhausting part 160 exhausts the heat. Thus, the heat exhausting part 160 may prevent the heat inputted from the external system from being transmitted into the semiconductor package. For example, the heat exhausting part 160 may be a heat slug or a heat sink.

A bottom surface of the heat exhausting part 160 may have a concave-convex structure 165. In some embodiments, the concave-convex structure 165 may include concave regions and convex portions. The concave regions of the concave-convex structure 165 may be filled with the adhesive part 150 having fluidity, while the heat exhausting part 160 is pressed on the molding part 130 and the semiconductor chip 120 with a certain pressure. The concave-convex structure 165 of the heat exhausting part 160 will be described in more detail below.

The adhesive part 150 may be disposed between the heat exhausting part 160 and the top surface 122 of the semiconductor chip 120, in FIG. 1A, and between the heat exhausting part 160 and the molding part 130. The heat exhausting part 160 may be adhered to the semiconductor chip 120 and the molding part 130 by the adhesive part 150. In some embodiments, the adhesive part 150 may be adhered to the concave-convex structure 165 of the heat exhausting part 160.

The adhesive part 150 may be disposed between the heat exhausting part 160 and the top surface 123 of the semiconductor chip 120a, in FIGS. 1B and 1C, and between the heat exhausting part 160 and the molding part 130. The heat exhausting part 160 may be adhered to the semiconductor chip 120a and the molding part 130 by the adhesive part 150. In some embodiments, the adhesive part 150 may be adhered to the concave-convex structure 165 of the heat exhausting part 160.

The adhesive part 150 may include a fluid material. The adhesive part 150 may be adhered by heat and/or ultraviolet rays. For example, the adhesive part 150 may include a thermal interface material (TIM).

As described above, an adhesive strength between the heat exhausting part 160 and the molding part 130 and between the heat exhausting part 160 and the semiconductor chip 120 is improved by the concave-convex structure 165 of the heat exhausting part 160.

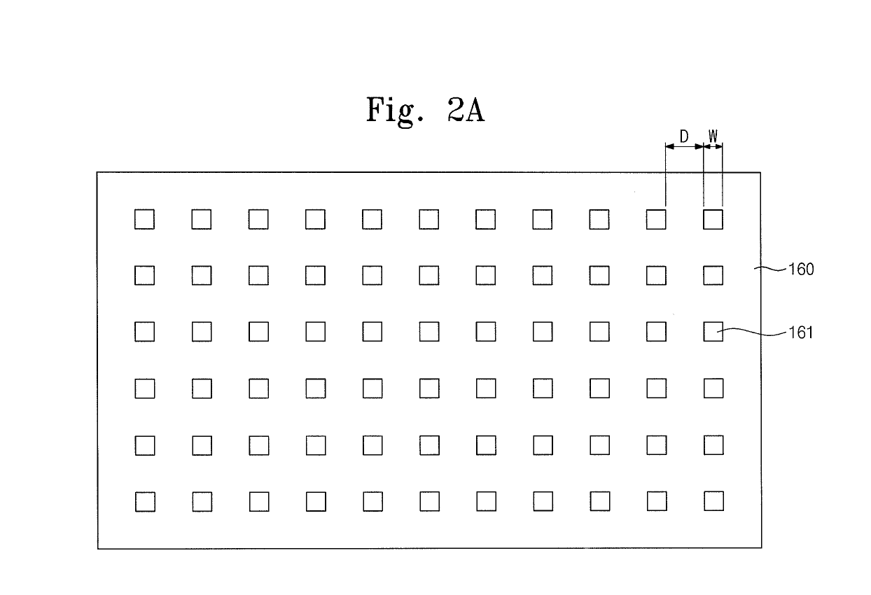

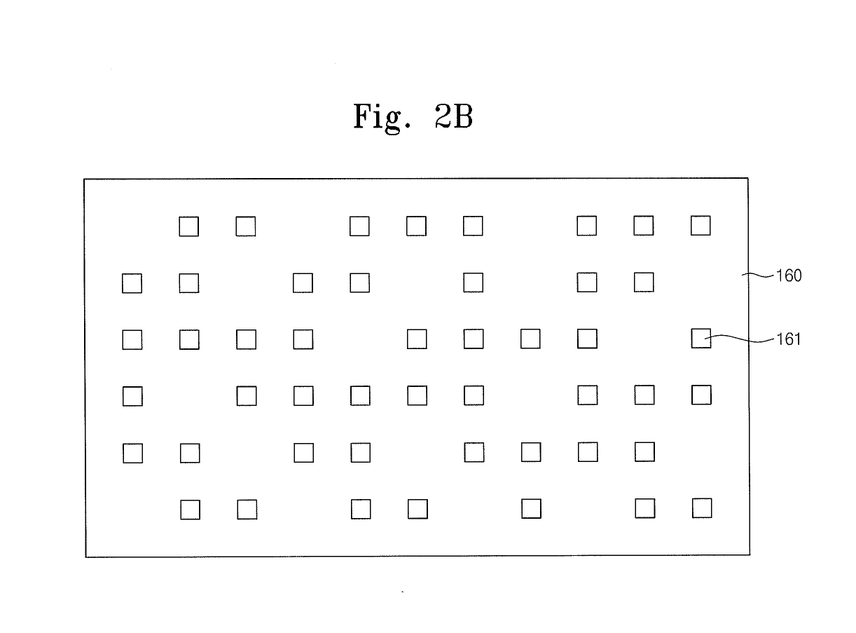

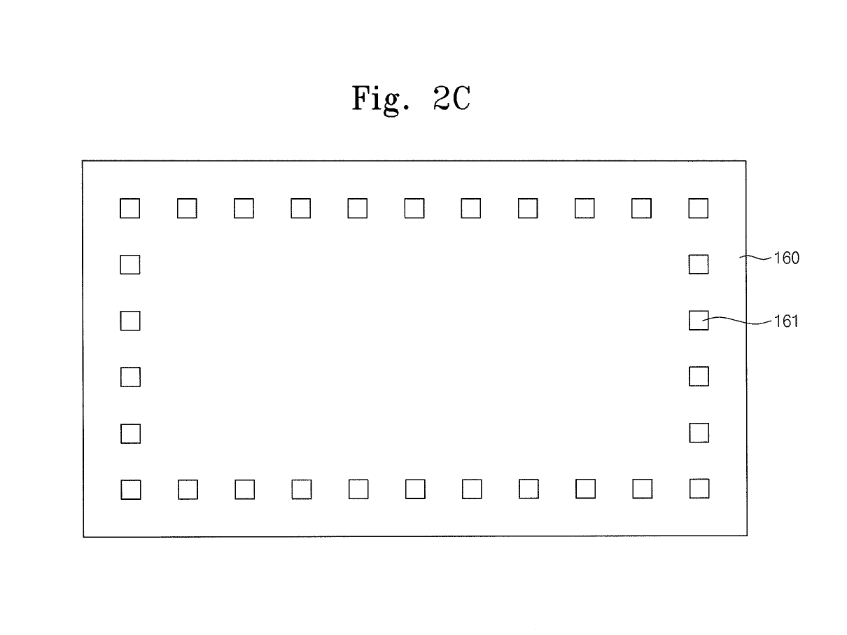

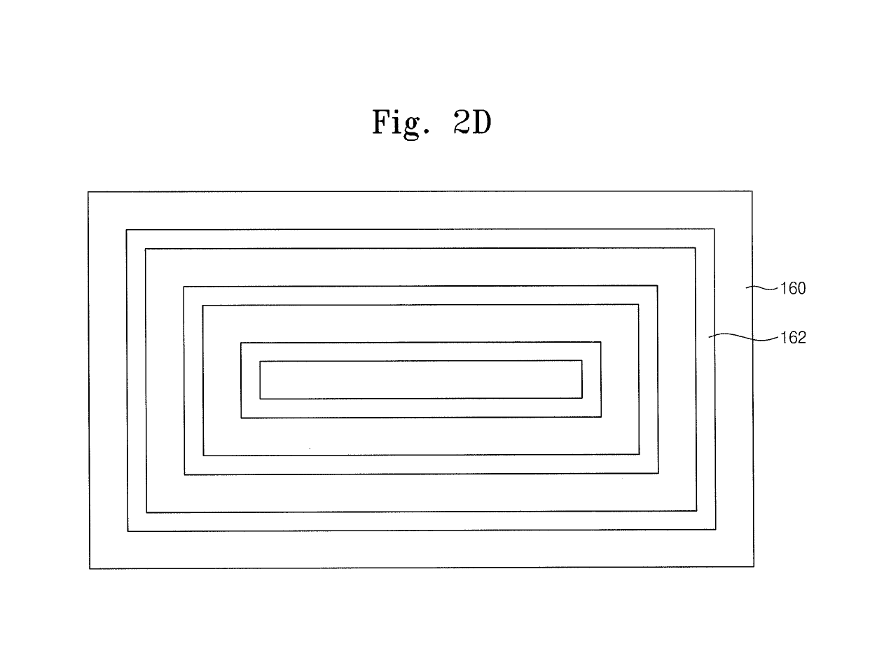

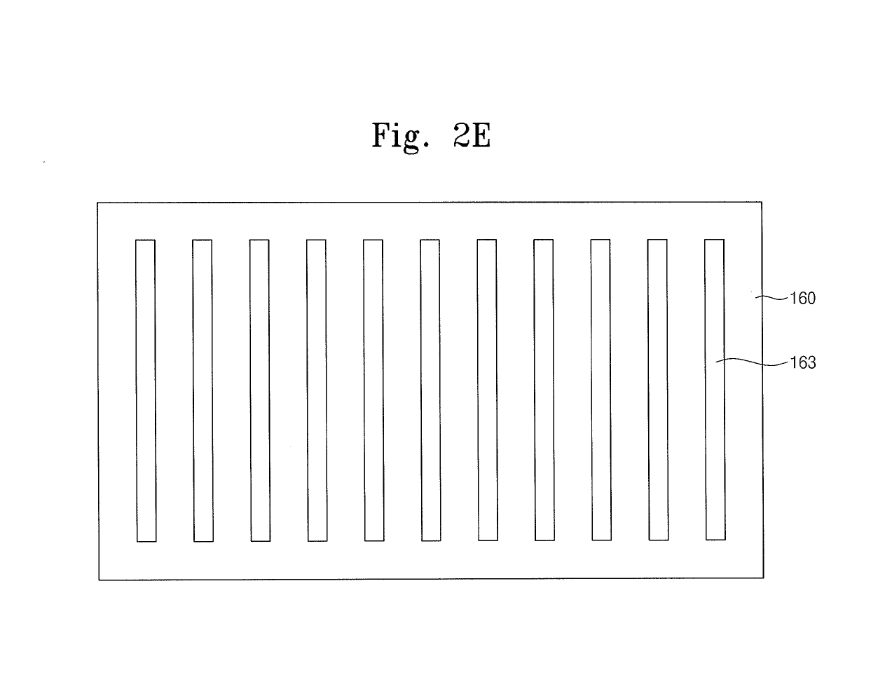

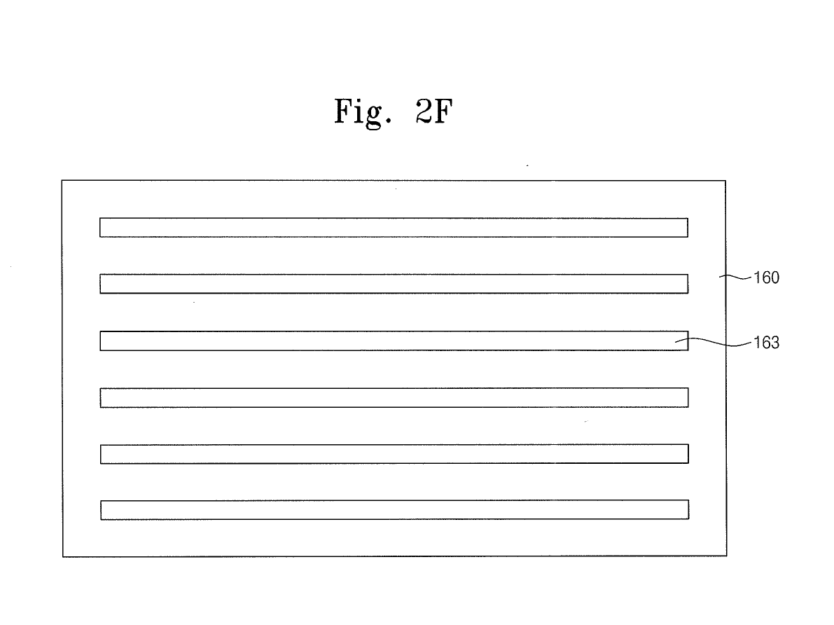

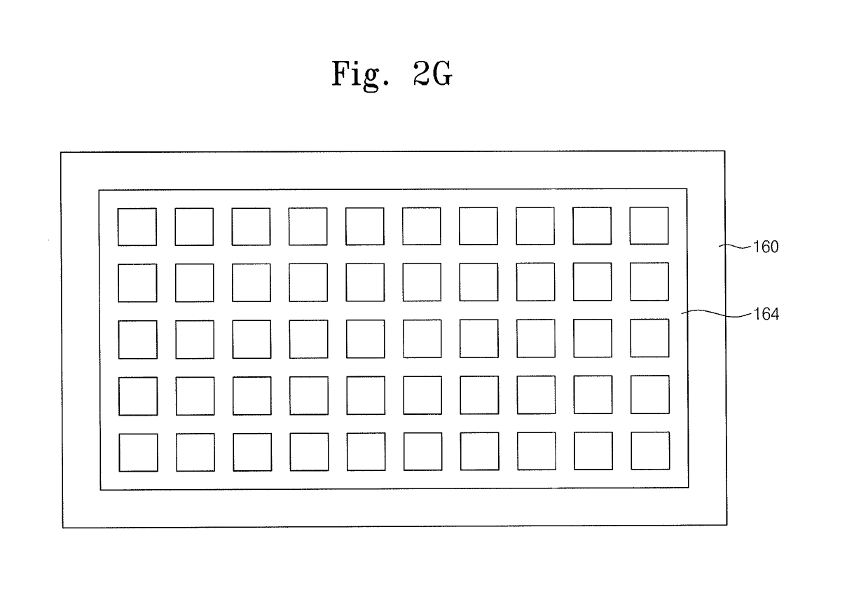

FIGS. 2A through 2G are plan views illustrating concave-convex structures of heat exhausting parts of semiconductor packages according to example embodiments of the inventive concepts.

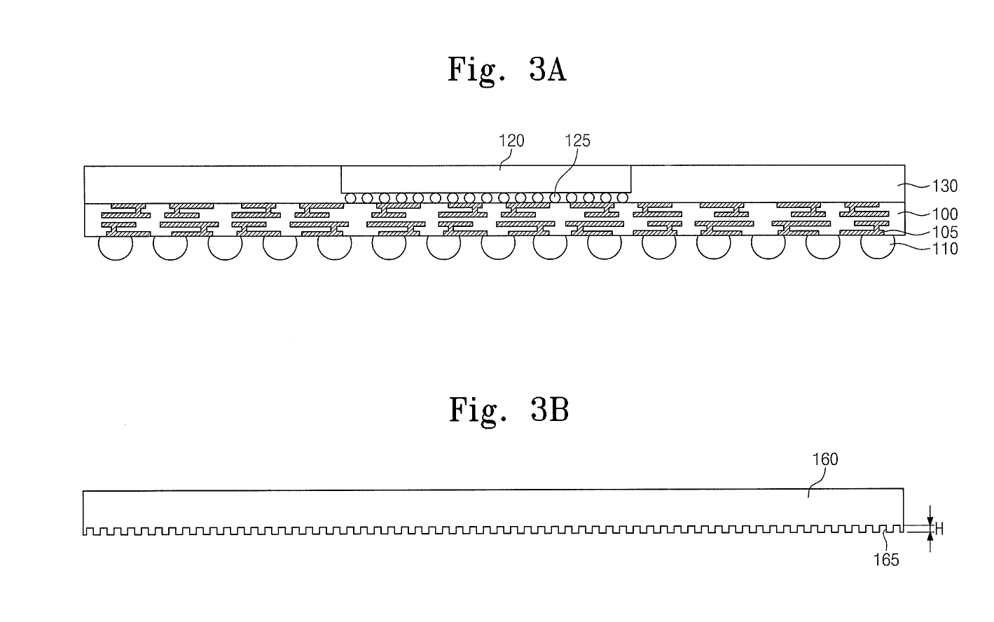

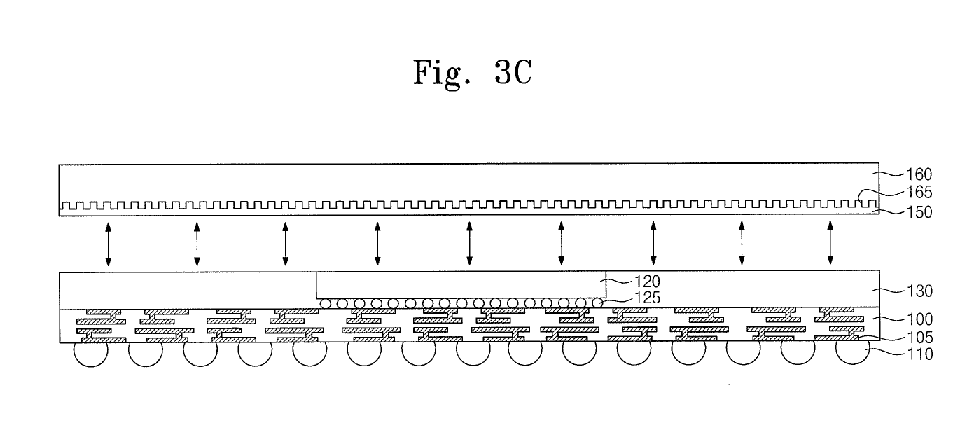

Referring to FIG. 2A, the concave-convex structure 165 may have convex portions 161 arranged along rows and columns at equal intervals in a plan view. Each of the convex portions 161 may have a quadrilateral shape. For example, referring to FIGS. 2A and 3B, a height H of the convex portion 161 may be within a range of about 5 μm to about 100 μm, and a width W of the convex portion 161 may be within a range of about 5 μm to about 1000 μm. A distance D between the convex portions 161 may be within a range of about 50 μm to about 3000 μm. In alternative embodiments to FIG. 2A, the convex portion 161 may have a cylindrical shape or a polygonal shape. Referring to FIG. 2B, spacing distances between the convex portions 161 may be irregular. Referring to FIG. 2C, the concave-convex structure 165 may have convex portions 161 arranged only along edges of the bottom surface of the heat exhausting part 160.

Referring to FIG. 2D, the concave-convex structure 165 may have a partition structure. For example, a convex partition 162 of the concave-convex structure 165 may have a quadrilateral ring-shape in a plan view, and a plurality of partitions 162 having quadrilateral ring-shapes may be disposed to be concentric with each other. In alternative embodiments to FIG. 2D, the partition 162 may have a circular shape or a polygonal ring in a plan view, and/or a spacing distance between the partitions 162 may be varied.

Referring to FIGS. 2E and 2F, the concave-convex structure 165 may include convex portions 163 having line-shapes extending in one, single direction in a plan view. FIG. 2E illustrates convex portions 163 extending in a first direction and FIG. 2F illustrates convex portions 163 extending in a second direction.

Referring to FIG. 2G, the concave-convex structure 165 may include a convex portion 164 having a mesh structure. Alternatively, the concave-convex structure 165 may include a concave region having a mesh structure. In alternative embodiments to FIG. 2G, the concave-convex structure 165 may include a concave region or convex portion having a honeycomb-shape.

The concave-convex structures 165 in FIGS. 2A to 2G may be described as examples. However, the concave-convex structure 165 of the heat exhausting part 160 is not limited to the concave-convex structures 165 illustrated in FIGS. 2A to 2G. According to embodiments of the inventive concepts, the concave-convex structure 165 may have any one of various shapes capable of improving the adhesive strength between the heat exhausting part 160 and the adhesive part 150.

FIGS. 3A through 3C are cross-sectional views illustrating a method of manufacturing a semiconductor package according to example embodiments of the inventive concepts.

Referring to FIG. 3A, a semiconductor chip 120 may be mounted on a substrate 100.

Connection patterns 125 may be formed between the semiconductor chip 120 and the substrate 100. The semiconductor chip 120 may be electrically connected to the substrate 100 through the connection patterns 125.

Subsequently, the molding part 130 may be formed on the substrate 100 having the semiconductor chip 120 and the connection patterns 125. The molding part 130 may expose a top surface of the semiconductor chip 120 and be formed to have an eMUF structure capable of omitting an underfill process. Thus, manufacturing of the semiconductor package may be simplified.

In FIG. 3A, external terminals 110 may be bonded to one surface of the substrate 100. However, the inventive concepts are not limited thereto. The process of bonding the external terminals 110 may be performed in a subsequent process.

Referring to FIG. 3B, a heat exhausting part 160 having a concave-convex structure 165 may be prepared. The concave-convex structure 165 may be formed at one surface of the heat exhausting part 160.

According to some embodiments of the inventive concepts, the concave-convex structure 165 may be formed using a laser on the one surface of the heat exhausting part 160. According to other example embodiments of the inventive concepts, the concave-convex structure 165 may be formed using a mold having a shape of the concave-convex structure 165.

Referring to FIG. 3C, an adhesive part 150 may be formed to fill a concave region of the concave-convex structure 165. The adhesive part 150 may be adhered to the heat exhausting part 160.

Next, the heat exhausting part 160 to which the adhesive part 150 is adhered may be moved onto the semiconductor chip 120 and the molding part 130 and then the adhesive part 150 may be pressed on the molding part 130 and the semiconductor chip 120 with a predetermined pressure. In this embodiment, the fluid adhesive part 150 may completely fill the concave regions of the concave-convex structure 165. The adhesive part 150 may be formed on top surfaces of the molding part 130 and the semiconductor chip 120 without cutting.

As a result, it is possible to improve an adhesive strength between the adhesive part 150 and the heat exhausting part 160 by the concave-convex structure 165 according to example embodiments of the inventive concepts.

Referring to FIG. 1A again, the adhesive part 150 may be adhered by heat and/or ultraviolet rays, such that the heat exhausting part 160 may be fixed on the semiconductor chip 120.

The semiconductor package according to embodiments may include the molding part 130 of the eMUF structure, such that the processing steps of manufacturing the semiconductor package may be simplified and the adhesive strength between the adhesive part 150 and the heat exhausting part 160 may be improved by the concave-convex structure 165 of the heat exhausting part 160.

While the method of manufacturing a semiconductor package is described in connection with FIG. 1A, the method may also be applied to the embodiments of FIGS. 1B and 1C.

Table 1 shows values measured from a pull test for confirming the adhesive strength between the heat exhausting part with the concave-convex structure and the adhesive part and an adhesive strength between a general heat exhausting part without the concave-convex structure and an adhesive part.

TABLE 1

| | | Heat exhausting part |
|---|---|---|
| | General heat exhausting | having concave-convex |
| | part (no concave- | structure (embodiments of |
| Pull test | convex structure) | the inventive concept) |
| Maximum value | 82.95 Kgf | 98.95 Kgf |
| Minimum value | 80.12 Kgf | 83.15 Kgf |
| Mean value | 81.52 Kgf | 91.08 Kgf |

As described in Table 1, the adhesive strength between the heat exhausting part with the concave-convex structure and the adhesive part is greater than the adhesive strength between the general heat exhausting part without the concave-convex structure and the adhesive part. That is, the adhesive strength according to embodiments of the inventive concepts is increased by about 10% of the adhesive strength of the general heat exhausting part.

[Applications]

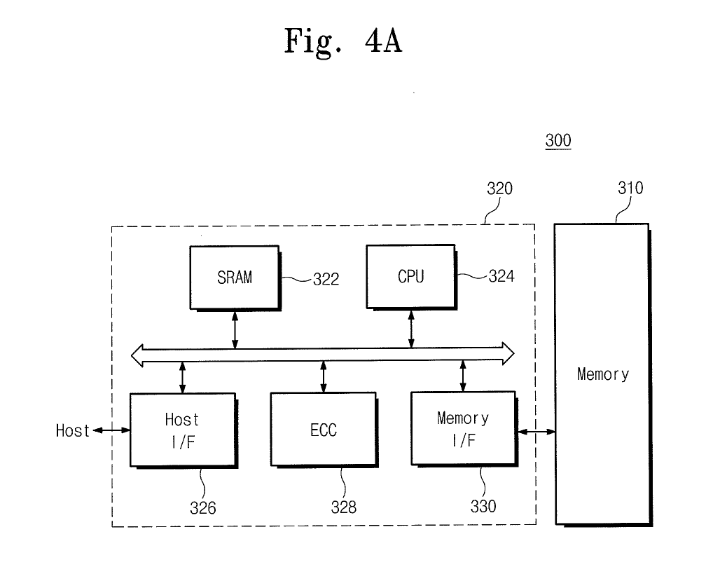

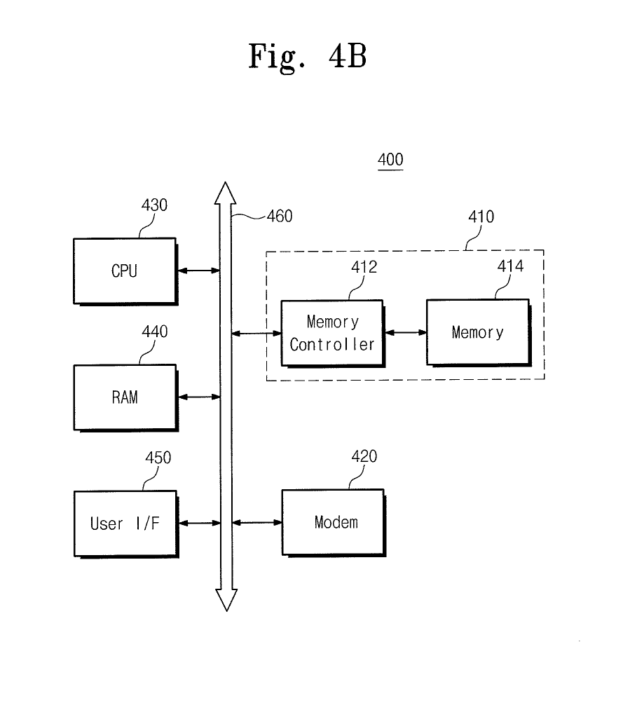

FIG. 4A is schematic block diagram illustrating a memory card including semiconductor packages according to the example embodiments of the inventive concepts.

Referring to FIG. 4A, the semiconductor package according to the aforementioned embodiments of the inventive concept may be applied to a memory card 300. For example, the memory card 300 may include a memory controller 320 that controls data communication between a host and a memory device 310. The memory controller 320 may include a static random access memory (SRAM) device 322, an operation memory of a central processing unit (CPU) 324, a host interface unit 326, an error check and correction (ECC) block 328 and a memory interface unit 330 which are coupled to each other through a bus. The SRAM device 322 may be used as an operation memory of the CPU 324. The host interface unit 326 may be configured to include a data communication protocol between the memory card 300 and the host. The ECC block 328 may detect and correct errors of data which are read out from the memory device 310. The memory interface unit 330 may interface with the memory device 310. The CPU 324 controls the overall operations of the memory controller 320.

The memory device 310 applied to the memory card 300 may include the semiconductor package according to example embodiments of the inventive concepts. Thus, the adhesive strength between the heat exhausting part and the semiconductor chip may increase, thus, improving reliability of the semiconductor package.

FIG. 4B is schematic block diagram illustrating a system including semiconductor packages according to the example embodiments of the inventive concepts.

Referring to FIG. 4B, an information processing system 400 may include the semiconductor package according to embodiments of the inventive concept. The information processing system 400 may include a mobile device or a computer. For example, the information processing system 400 may include a modem 420, a central processing unit (CPU) 430, a random access memory (RAM) 440, and a user interface unit 450 that are electrically connected to a memory system 410 through a system bus 460. The memory system 410 may store data processed by the central processing unit 430 or data inputted from an external device. The memory system 410 may include a memory device 414 and a memory controller 412. The memory system 410 may be substantially the same as the memory card 300 described in connection with FIG. 4A. The information processing system 400 may be realized as a memory card, a solid state disk (SSD) device, a camera image sensor and any other type of application chipset. For example, the memory system 410 may consist of the SSD device. In this embodiment, the information processing system 400 may stably and reliably store massive data.

According to the example embodiments of the inventive concepts, the concave-convex structure is formed at the interface between the heat exhausting part and the adhesive part, such that the adhesive strength between the heat exhausting part and the adhesive part may be improved. Thus, it is possible to improve electrical reliability of the semiconductor package including the heat exhausting part and the adhesive part.

While the inventive concepts have been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concepts is to be determined by the broadest permissible interpretation of the following claims and their equivalents, and shall not be restricted or limited by the foregoing description.

1. A semiconductor package comprising:
a semiconductor chip mounted on a substrate;
a molding part protecting the semiconductor chip, the molding part having a top surface at a height substantially equal to that of a top surface of the semiconductor chip;
a heat exhausting part on the molding part and the semiconductor chip; and
an adhesive part between the heat exhausting part and the molding part and between the heat exhausting part and the semiconductor chip,
wherein an interface between the heat exhausting part and the adhesive part has a concave-convex structure.

2. The semiconductor package of claim 1, wherein the concave-convex structure is at the heat exhausting part.

3. The semiconductor package of claim 1, wherein the molding part has an exposed molded underfill (eMUF) structure exposing the top surface of the semiconductor chip.

4. The semiconductor package of claim 1, further comprising:
connection patterns disposed between the semiconductor chip and the substrate,
wherein the connection patterns electrically connect the semiconductor chip to the substrate; and
wherein the molding part covers the connection patterns.

5-9. (canceled)

10. A semiconductor package comprising:
a semiconductor chip mounted on a substrate;
a molding part protecting the semiconductor chip and exposing a top surface of the semiconductor chip;
a heat exhausting part on the molding part and the semiconductor chip, a first surface of the heat exhausting part having a concave-convex structure; and
an adhesive part between the top surface of the semiconductor chip and the heat exhausting part filling concave regions of the concave-convex structure.

11. The semiconductor package of claim 10, wherein the molding part covers a sidewall and a bottom surface of the semiconductor chip.

12. The semiconductor package of claim 10, wherein the molding part has an exposed molded underfill (eMUF) structure exposing the top surface of the semiconductor chip.

13. The semiconductor package of claim 10, wherein the adhesive part is further between the molding part and the heat exhausting part.

14. The semiconductor package of claim 10, further comprising:
connection patterns disposed between the semiconductor chip and the substrate,
wherein the connection patterns electrically connect the semiconductor chip to the substrate; and
wherein the molding part covers the connection patterns.

15. The semiconductor package of claim 10, wherein the molding part comprises a top surface at a height substantially equal to that of a top surface of the semiconductor chip.

16. The semiconductor package of claim 10, wherein the semiconductor chip comprises a plurality of semiconductor chips vertically stacked.

17. The semiconductor package of claim 16, wherein the plurality of semiconductor chips are at least one of electrically connected to the substrate and electrically connected to each other.

18. The semiconductor package of claim 16, wherein at least one of the plurality of semiconductor chips comprises a through-electrode.

19. The semiconductor package of claim 10, wherein the concave-convex structure comprises at least one of convex portions along rows and columns at equal intervals, convex portions at irregular intervals, convex portions only along outer edges of the heat exhausting part, a partition structure, convex portions having line-shapes, and convex portions having a mesh structure.

20. The semiconductor package of claim 10 further comprising external terminals at a surface of the substrate opposite the surface of the substrate to which the semiconductor chip is mounted.
